(19) United States
(12) Patent Application Publication
(10) Pub. No.: US 2021/0066321 A1
(43) Pub. Date: Mar. 4, 2021

(54) MEMORY DEVICE

(71) Applicant: ELECTRONICS AND TELECOMMUNICATIONS RESEARCH INSTITUTE, Daejeon (KR)

(72) Inventors: JungWook LIM, Daejeon (KR); Sun Jin YUN, Daejeon (KR)

(73) Assignee: ELECTRONICS AND TELECOMMUNICATIONS RESEARCH INSTITUTE, Daejeon (KR)

(21) Appl. No.: 16/993,954

(22) Filed: Aug. 14, 2020

(30) Foreign Application Priority Data
Sep. 3, 2019 (KR) 10-2019-0109058
Apr. 23, 2020 (KR) 10-2020-0049565

(51) Int. Cl. H01L 27/11517; G11C 5/02; H01L 29/423; H01L 27/11563

(52) U.S. Cl. CPC H01L 27/11517; H01L 27/11563; H01L 29/4232; G11C 5/025

(57) ABSTRACT

Provided is a memory device including a gate electrode, a first insulation layer on the gate electrode, a first conductive pattern and a second conductive pattern, which are spaced apart from each other on the first insulation layer, a channel pattern disposed on the first insulation layer to connect the first conductive pattern and the second conductive pattern, and an interface layer disposed between the channel pattern and the first insulation layer and having a hydrogen atom content ratio (atomic %) greater than that of the first insulation layer.

### CROSS-REFERENCE TO RELATED APPLICATIONS

This U.S. non-provisional patent application claims priority under 35 U.S.C. § 119 of Korean Patent Application No. 10-2019-0109058, filed on Sep. 3, 2019 and 10-2020-049565, filed on Apr. 23, 2020, the entire contents of which are hereby incorporated by reference.

### BACKGROUND

The present disclosure herein relates to a memory device, and more particularly, to a fusion memory device capable of calculating and storing data.

A memory device includes a memory region for storing data and a logic region for operating and calculating the memory region. Although the memory region and the logic region are generally independently provided, logic-memory fusion devices performing both memorizing and calculating have been recently researched and developed. The logic-memory fusion device may be used for a synapse imitation device for an artificial intelligence device and have a representative advantage of extremely low power consumption and standby power. Although a synapse imitation device capable of performing a ultrahigh speed operation by using tunneling was suggested in the past, a performance of the synapse imitation device is not sufficient for mass production. In recent years, two-terminal memristor logic-memory fusion devices and transistor-type logic-memory fusion devices having a three terminal structure are continuously suggested.

### SUMMARY

The present disclosure provides a memory device capable of performing storage and calculation of data.

The object of the present invention is not limited to the aforesaid, but other objects not described herein will be clearly understood by those skilled in the art from descriptions below.

An embodiment of the inventive concept provides a memory device including: a gate electrode; a first insulation layer on the gate electrode; a first conductive pattern and a second conductive pattern, which are spaced apart from each other on the first insulation layer; a channel pattern disposed on the first insulation layer to connect the first conductive pattern and the second conductive pattern; and an interface layer disposed between the channel pattern and the first insulation layer and having a hydrogen atom content ratio (atomic %) greater than that of the first insulation layer.

In an embodiment, the first insulation layer and the channel pattern may be spaced apart from each other with the interface layer therebetween.

In an embodiment, the interface layer may have a thickness less than that of each of the first insulation layer and the channel pattern.

In an embodiment, the memory device may further include a second insulation layer disposed between the first insulation layer and the gate electrode, and the first insulation layer and the second insulation layer may have different oxygen atom content ratios (atomic %).

In an embodiment, the interface layer may cover at least a portion of a side surface of the first insulation layer.

In an embodiment, the memory device may further include a pulse generator that is electrically connected to the gate electrode.

In an embodiment of the inventive concept, a memory device includes: a first gate electrode and a second gate electrode, which are spaced apart from each other in a first direction; a first channel pattern on the first gate electrode; a second channel pattern on the second gate electrode; a first insulation layer disposed between the first gate electrode and the first channel pattern and between the second gate electrode and the second channel pattern; and a first conductive pattern and a second conductive pattern on the first insulating layer. The first conductive pattern and the second conductive pattern are spaced apart from each other in a second direction crossing the first direction. Here, each of the first channel pattern and the second channel pattern connects the first conductive pattern and the second conductive pattern.

In an embodiment, the memory device may further include a first interface layer disposed between the first channel pattern and the first insulation layer and a second interface layer disposed between the second channel pattern and the first insulation layer.

In an embodiment, each of the first interface layer and the second interface layer may have a hydrogen atom content ratio (atomic %) greater than that of the first insulation layer.

In an embodiment, the memory device may further include a second insulation layer disposed between the first insulation layer and the first and second gate electrodes, and the first insulation layer and the second insulation layer may have different oxygen atom ratios (atomic %).

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a schematic perspective view illustrating a memory device according to embodiments of the inventive concept;

FIG. 2 is a circuit diagram representing the memory device according to the embodiments of the inventive concept;

FIG. 3 is a cross-sectional view illustrating the memory device according to the embodiments of the inventive concept;

FIG. 4 is an enlarged cross-sectional view illustrating a portion AA of FIG. 3;

FIG. 5A is a graph representing a pulse voltage applied to a gate of the memory device according to the embodiments of the inventive concept;

FIG. 5B is a graph representing a drain current based on a pulse and a voltage applied to the gate of the memory device according to the embodiments of the inventive concept;

FIG. 6A is a graph representing a pulse voltage applied to a gate of the memory device according to the embodiments of the inventive concept;

FIG. 6B is a graph representing a drain current based on a pulse and a voltage applied to the gate of the memory device according to the embodiments of the inventive concept;

FIG. 7 is a graph representing a drain current based on the number of pulses applied to the gate of the memory device according to the embodiments of the inventive concept;

FIG. 8 is a graph representing a synapse imitation operation of the memory device according to the embodiments of the inventive concept.

FIGS. 9A and 9B are enlarged cross-sectional views illustrating the memory device according to the embodiments of the inventive concept and corresponding to the portion AA of FIG. 3;

FIG. 10 is a cross-sectional view illustrating the memory device according to the embodiments of the inventive concept;

FIG. 11 is a plan view illustrating a memory device according to the embodiments of the inventive concept;

FIG. 12 is a cross-sectional view taken along line I-I′ of FIG. 11;

FIG. 13 is a plan view illustrating the memory device according to the embodiments of the inventive concept;

FIGS. 14A, 14B, and 14C are cross-sectional views taken along line I-I′, line II-II′, and line III-III′ of FIG. 13, respectively; and

FIGS. 15 to 18 are cross-sectional views illustrating a method for manufacturing the memory device according to the embodiment of the inventive concept.

### DETAILED DESCRIPTION

Advantages and features of the present invention, and implementation methods thereof will be clarified through following embodiments described with reference to the accompanying drawings. The present invention may, however, be embodied in many different forms and should not be construed as being limited to the embodiments set forth herein. Rather, these embodiments are provided so that this disclosure will be thorough and complete, and will fully convey the concept of the invention to those skilled in the art. Further, the present invention is only defined by scopes of claims. Like reference numerals refer to like elements throughout.

In the following description, the technical terms are used only for explaining a specific exemplary embodiment while not limiting the present disclosure. The terms of a singular form may include plural forms unless referred to the contrary. The meaning of ‘comprises’ and/or ‘comprising’ specifies a component, a step, an operation and/or an element does not exclude other components, steps, operations and/or elements.

Additionally, the embodiment in the detailed description will be described with sectional views as ideal exemplary views of the present invention. Also, in the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. For example, an etched region having a right angle illustrated in the drawings may have a round shape or a shape having a predetermined curvature. Areas exemplified in the drawings have general properties, and are used to illustrate a specific shape of a semiconductor package region. Thus, this should not be construed as limited to the scope of the present invention.

Hereinafter, exemplary embodiments will be described in detail with reference to the accompanying drawings.

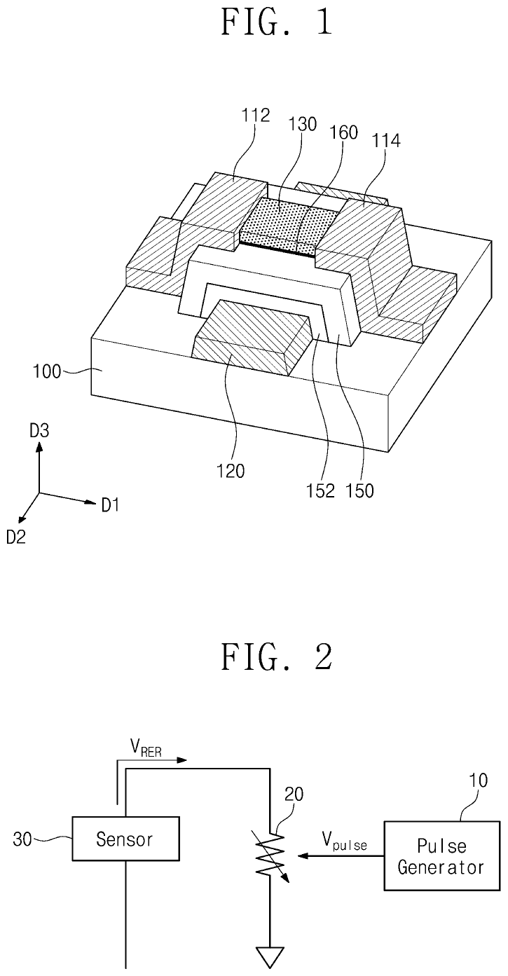

FIG. 1 is a schematic perspective view illustrating a memory device according to embodiments of the inventive concept. FIG. 2 is a circuit diagram representing the memory device according to the embodiments of the inventive concept.

Referring to FIGS. 1 and 2, the memory device according to an embodiment of the inventive concept may include a substrate 100, a gate electrode 120, a first insulation layer 150, a second insulation layer 152, an interface layer 160, a channel pattern 130, a first conductive pattern 112, and a second conductive pattern 114.

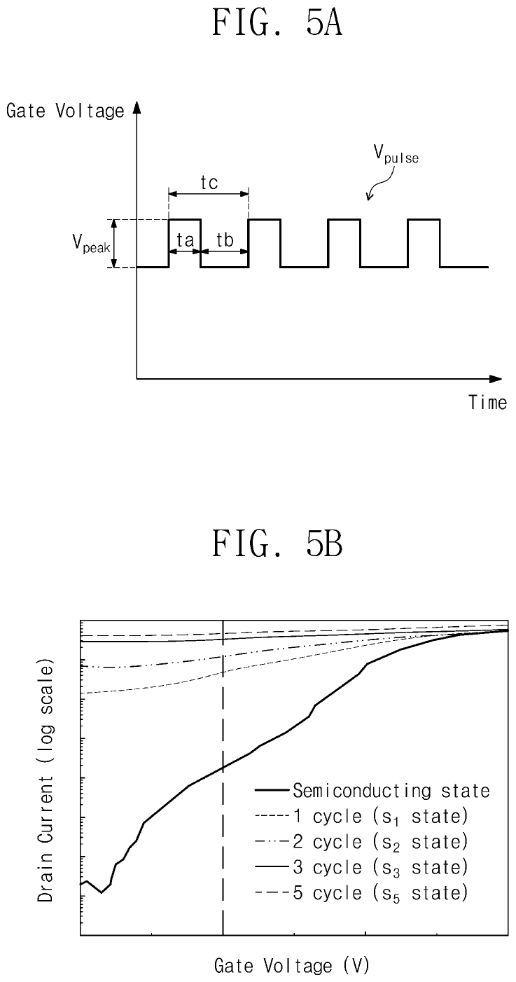

The gate electrode 120 may be spaced apart form the channel pattern 130 with the second insulation layer 152, the first insulation layer 150, and the interface layer 160 therebetween. The gate electrode 120 may receive a pulse voltage Vₚᵤₗₛₑ from a pulse generator 10 to vary a resistance of the channel pattern 130. Methods of applying the pulse voltage Vₚᵤₗₛₑ to the gate electrode 120 to vary the resistance of the channel pattern 130 will be described in detail with reference to FIGS. 5A to 7. The channel pattern 130 may have a multi-state resistance according to the pulse voltage Vₚᵤₗₛₑ applied to the gate electrode 120. The channel pattern 130 may function as a variable resistance 20.

The first conductive pattern 112 and the second conductive pattern 114 may be a source or drain electrode of the memory device. For example, the first conductive pattern 112 may be one of the source and drain electrodes, and the second conductive pattern 114 may be the other of the source and drain electrodes, which is different from the first conductive pattern 112. The first conductive pattern 112 and the second conductive pattern 114 may be connected to a sensor 30. The sensor 30 may include, e.g., a sense amplifier. The sensor 30 may read data stored in the memory device through a reference voltage V_{ref}. The stored data may be, e.g., a drain current value corresponding a resistance value of the channel pattern 130 or the reference voltage V_{ref}.

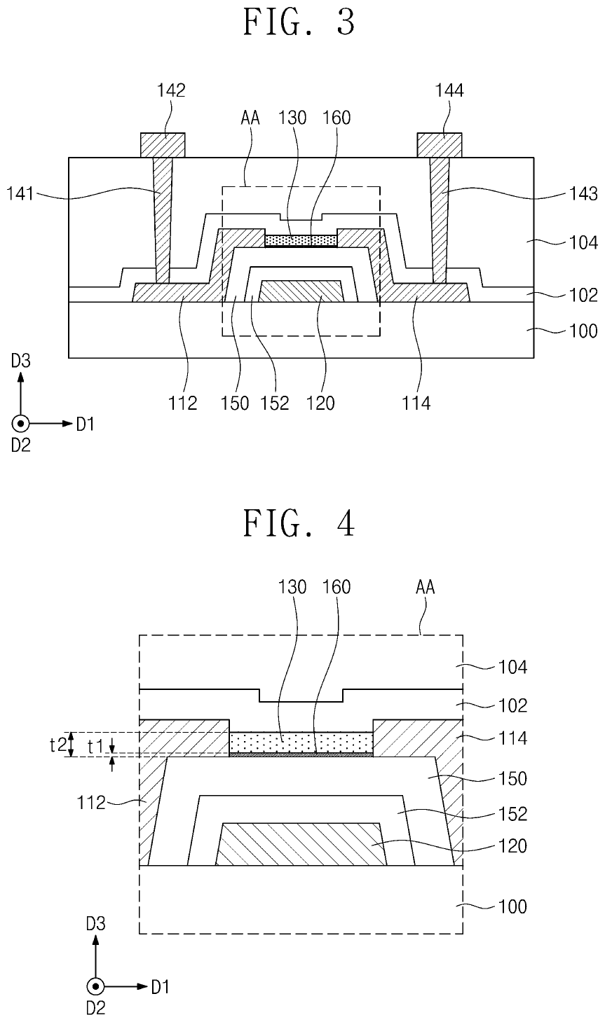

FIG. 3 is a cross-sectional view illustrating the memory device according to the embodiments of the inventive concept. FIG. 4 is an enlarged cross-sectional view illustrating a portion AA of FIG. 3.

Specifically, referring to FIGS. 3 to 4, the substrate 100 may be provided below the memory device. The substrate 100 may include an insulation substrate or a semiconductor substrate. The substrate 100 may include, e.g., silicon (Si), silicon carbide (SiC), germanium (Ge), Group III-V compound semiconductor, and a combination thereof. When the substrate 100 includes a semiconductor material, the substrate 100 may further include an oxide layer provided through a thermal oxidation process thereon. The substrate 100 may include a flexible substrate. The substrate 100 may include, e.g., polyimide (PI), polyethylene terephthalate (PET), poly ether sulfone (PES), or polyethylene naphthalate (PEN). The substrate 100 may be a transparent or translucent substrate. For example, the substrate 100 may include glass or sapphire.

The gate electrode 120 may be provided on a top surface of the substrate 100. The gate electrode 120 may include aluminum (Al), copper (Cu), silver (Ag), and gold (Au). The gate electrode 120 may include doped silicon or germanium. The gate electrode 120 may include a transparent or translucent conductive material. For example, the gate electrode 120 may include ITO, FTO, SnO₂ and ZnO.

The second insulation layer 152 and the first insulation layer 150 may be disposed on the gate electrode 120. The second insulation layer 152 may cover a top surface and side surfaces of the gate electrode 120. The first insulation layer 150 may be disposed on the second insulation layer 152 to cover surfaces of the second insulation layer 152. The gate electrode 120 may be electrically insulated from the channel pattern 130 by the first insulation layer 150 and the second insulation layer 152. For example, the first insulation layer 150 may include one of ZrO₂, Al₂O₃, HfO₂, SiO₂, Ta₂O₅, AlZrO, AlSiO, AlSiO and a combination thereof. For example, the second insulation layer 152 may include one of a silicon oxide, ZrO₂, Al₂O₃, HfO₂, SiO₂, Ta₂O₅, AlZrO, AlSiO, AlSiO and a combination thereof.

The first insulation layer 150 may include a vacancy therein. The first insulation layer 150 may include an oxygen vacancy. According to an embodiment, the first insulation layer 150 may be provided, and then a high pressure hydrogen annealing process may be performed on the first insulation layer 150. Hydrogen atoms injected to the first insulation layer 150 through the high pressure hydrogen annealing process may desorb oxygen atoms existing in the first insulation layer 150. The oxygen vacancy may be defined in a place from which the oxygen is desorbed. The first insulation layer 150 and the second insulation layer 152 may have different oxygen atom content ratios (atomic %) from each other. The first insulation layer 150 may have an oxygen atom content ratio (atomic %) less than that of the second insulation layer 152. The first insulation layer 150 may function as a charge inducing layer for providing a hole to an interface layer 160 that will be described later.

The first conductive pattern 112 and the second conductive pattern 114 may be disposed on the first insulation layer 150. The first conductive pattern 112 and the second conductive pattern 114 may be spaced apart from each other in a first direction D1. The first conductive pattern 112 and the second conductive pattern 114 may cover a portion of a top surface and a portion of a side surface of the first insulation layer 150. Each of the first conductive pattern 112 and the second conductive pattern 114 may extend to the top surface of the substrate 100. Each of the first conductive pattern 112 and the second conductive pattern 114 may include aluminum (Al), copper (Cu), silver (Ag), and gold (Au). Each of the first conductive pattern 112 and the second conductive pattern 114 may include doped silicon or germanium. Each of the first conductive pattern 112 and the second conductive pattern 114 may include a transparent or translucent conductive material. Each of the first conductive pattern 112 and the second conductive pattern 114 may include, e.g., ITO, FTO, SnO₂ and ZnO.

The channel pattern 130 may be disposed on the first insulation layer 150. The channel pattern 130 may be disposed between the first conductive pattern 112 and the second conductive pattern 114 and connect the first conductive pattern 112 and the second conductive pattern 114 to each other. In other words, the first conductive pattern 112 may be disposed on one end of the first insulation layer 150, and the second conductive pattern 114 may be disposed on the other end of the first insulation layer 150. The channel pattern 130 may have a thickness t2 of, e.g., about 3 nm to about 200 nm. The channel pattern 130 may include an oxide semiconductor. For example, the channel pattern 130 may include one of ZnO, TiO₂, In₂O₃, SnO₂ and a combination thereof. The channel pattern 130 may be provided through atomic layer deposition (ALD) and/or chemical vapor deposition (CVD). The channel pattern 130 may be in-situ provided with the first insulation layer 150. The channel pattern 130 may have a resistance that is varied according to a voltage applied to the gate electrode 120. That is, a current value between the first conductive pattern 112 and the second conductive pattern 114 may be varied by applying a voltage to the gate electrode 120. The channel pattern 130 may have a semiconductor phase or a metal phase according to a magnitude and a pulse of the voltage applied to the gate electrode 120.

The interface layer 160 may be disposed between the channel pattern 130 and the first insulation layer 150. The interface layer 160 may have a hydrogen atom content ratio (atomic %) greater than that of the first insulation layer 150. The interface layer 160 may have a thickness t1 less than that of the channel pattern 130. The interface layer 160 may include hydrogen (H) atoms. For example, the interface layer 160 may further include, as a base material, one of ZrO₂, Al₂O₃, HfO₂, SiO₂, Ta₂O₅, AlZrO, AlSiO, AlSiO, ZnO, TiO₂, In₂O₃, SnO₂ and a combination thereof. The hydrogen atoms may be doped to the base material. The hydrogen atom may be an interstitial atom between lattices of crystal of the base material.

A first interlayer insulation layer 102 covering the gate electrode 120, the first insulation layer 150, the first conductive pattern 112, the second conductive pattern 114, and the channel layer 130 may be provided. The first interlayer insulation layer 102 may conformally cover the gate electrode 120, the first insulation layer 150, the first conductive pattern 112, the second conductive pattern 114, and the channel layer 130. A second interlayer insulation layer 104 may be provided on the first interlayer insulation layer 102. The second interlayer insulation layer 104 may cover the first interlayer insulation layer 102 and have a flat top surface.

A first conductive pad 142 and a second conductive pad 144 may be provided on the second interlayer insulation layer 104. The first conductive pad 142 may be electrically connected to the first conductive pattern 112 by a first contact plug 141. The second conductive pad 144 may be electrically connected to the second conductive pattern 114 by a second contact plug 143. The first contact plug 141 and the second contact plug 143 may pass through the first interlayer insulation layer 102 and the second interlayer insulation layer 104, respectively. According to embodiments, one of the first pad 142 and the second pad 144 may be electrically connected to the sensor that is described with reference to FIG. 2. The other of the first pad 142 and the second pad 144 may be grounded.

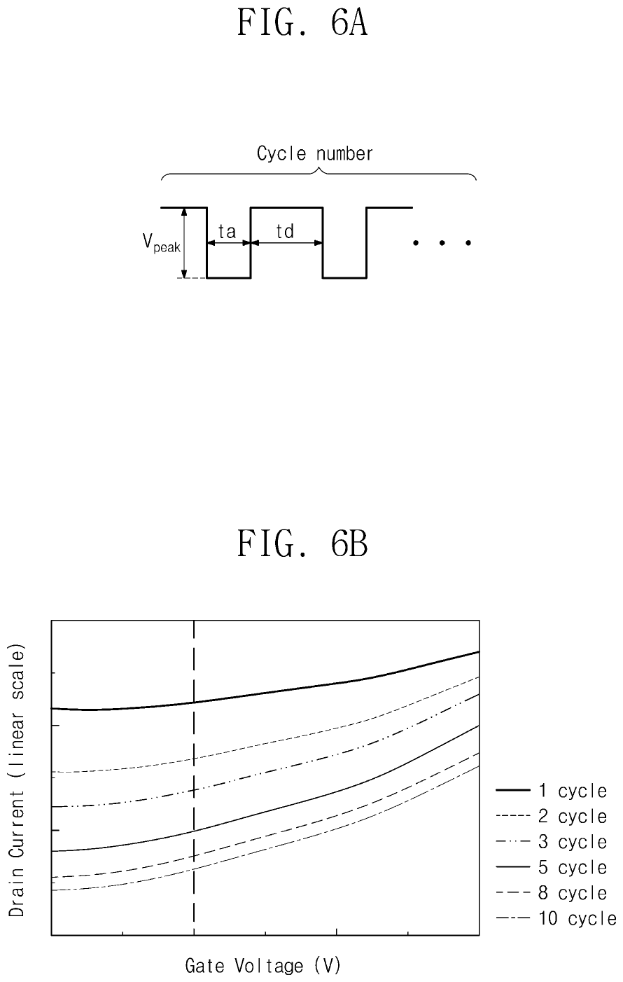

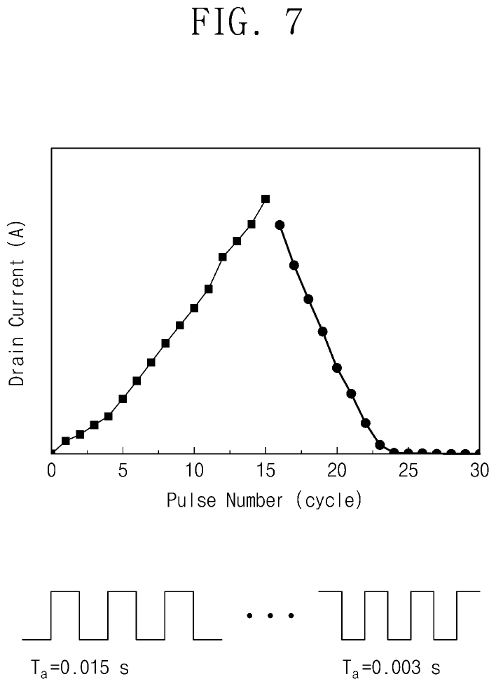

FIG. 5A is a graph representing a pulse voltage applied to the gate of the memory device according to the embodiments of the inventive concept. FIG. 5B is a graph representing a drain current based on a pulse and a voltage applied to the gate of the memory device according to the embodiments of the inventive concept. FIG. 6A is a graph representing a pulse voltage applied to a gate of the memory device according to the embodiments of the inventive concept. FIG. 6B is a graph representing a drain current based on a pulse and a voltage applied to the gate of the memory device according to the embodiments of the inventive concept. FIG. 7 is a graph representing a drain current based on the number of pulses applied to the gate of the memory device according to the embodiments of the inventive concept.

Referring to FIGS. 3, 5A and 5B, data may be recorded in the memory device. The pulse voltage Vₚᵤₗₛₑ may be applied to the gate electrode 120. As illustrated in FIG. 5A, the pulse voltage Vₚᵤₗₛₑ may have a shape in which a peak voltage Vₚₑₐₖ and a background voltage are periodically repeated. A pulse frequency tc of the pulse voltage Vₚᵤₗₛₑ may be the same as a sum of a duration time ta of one peak voltage Vₚₑₐₖ and a duration time tb of one background voltage. The duration time ta of the peak voltage Vₚₑₐₖ may be less than the duration time tb of the background voltage. According to embodiments, the background voltage may be about 0 V. The peak voltage Vₚₑₐₖ for recording data may have a positive value with respect to the background voltage.

The gate electrode 120 may control an electrical property of the channel pattern 130 through the pulse voltage Vₚᵤₗₛₑ. The channel pattern 130 may have a resistance that is varied according to the number of pulse cycles (i.e., the repeated number of the pulse frequency tc). For example, the resistance of the channel pattern 130 may be reduced as the number of the pulse cycles increases. Thus, as illustrated in FIG. 5B, as the number of the pulse cycles increases, a drain current flowing through the first conductive pad 142 or the second conductive pad 144 may increase. The drain current flowing through the first conductive pad 142 or the second conductive pad 144 may have a magnitude that is also varied according to a magnitude of the peak voltage Vₚₑₐₖ. When the pulse voltage Vₚᵤₗₛₑ has the same number of the pulse cycles, the magnitude of the drain current flowing through the first conductive pad 142 or the second conductive pad 144 may increase as the magnitude of the peak voltage Vₚₑₐₖ increases.

Referring to FIGS. 3, 6A and 6B, the data may be erased by applying the pulse voltage Vₚᵤₗₛₑ for erasing the data to the gate electrode 120 of the memory device, in which the data are recorded. The peak voltage Vₚₑₐₖ of the pulse voltage Vₚᵤₗₛₑ for erasing data may have a negative value with respect to the background voltage. The resistance of the channel pattern 130 may increase as the pulse voltage Vₚᵤₗₛₑ including the peak voltage Vₚₑₐₖ having the negative value is applied to the gate electrode 120. That is, the magnitude of the drain current flowing through the first conductive pad 142 or the second conductive pad 144 may be reduced.

As the number of pulse cycles of the pulse voltage Vₚᵤₗₛₑ applied to the gate electrode 120 increases, the resistance of the channel pattern 130 may increase. Thus, as illustrated in FIG. 5B, as the number of the pulse cycles increases, the drain current flowing through the first conductive pad 142 or the second conductive pad 144 may be reduced. The drain current flowing through the first conductive pad 142 or the second conductive pad 144 may have a magnitude that is also varied according to the magnitude of the peak voltage Vₚₑₐₖ. When the pulse voltage Vₚᵤₗₛₑ has the same number of the pulse cycles, the magnitude of the drain current flowing through the first conductive pad 142 or the second conductive pad 144 may increase as the magnitude of the peak voltage Vₚₑₐₖ increases.

Referring to FIGS. 3 and 7, the channel pattern 130 may have a multi-state resistance. Thus, the drain current flowing through the first conductive pad 142 or the second conductive pad 144 may have a magnitude that is also varied according to the resistance of the channel pattern 130. The memory device may read the data by reading the drain current flowing through the first conductive pad 142 or the second conductive pad 144. For example, the channel pattern 130 may have two or more resistance states, and the memory device according to the embodiments of the inventive concept may store at least 2-bit data for itself.

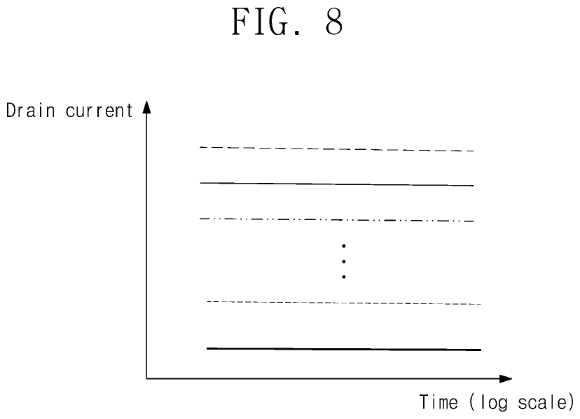

FIG. 8 is a graph representing a synapse imitation operation of the memory device according to the embodiments of the inventive concept.

Referring to FIG. 8, the drain current may gradually increase by applying the pulse voltage having a positive pulse peak to the memory device. Also, the drain current may gradually decrease by applying the pulse voltage having a negative pulse peak to the memory device.

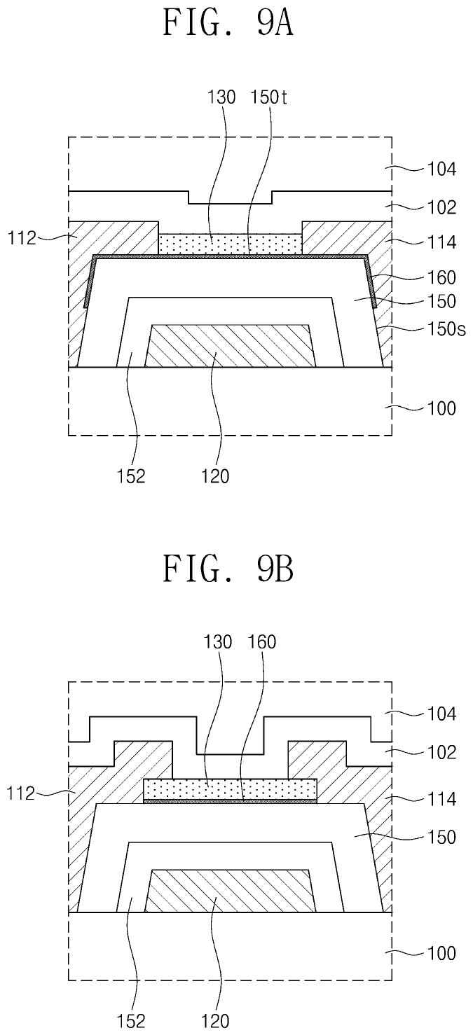

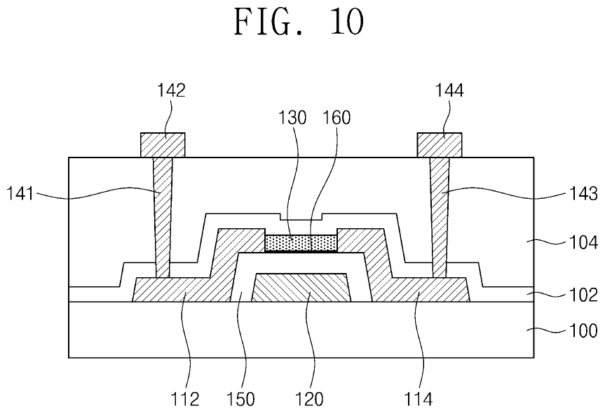

FIGS. 9A and 9B are enlarged cross-sectional views illustrating the memory device according to the embodiments of the inventive concept and corresponding to the portion AA of FIG. 3. For simplicity of explanation, detailed descriptions on duplicated components will be omitted.

Referring to FIG. 9A, the interface layer 160 may completely cover a top surface of the first insulation pattern 150. The interface layer 160 may cover at least a portion of a sidewall of the first insulation pattern 150.

Referring to FIG. 9B, the first conductive pad 142 and the second conductive pad 144 may cover a portion of a top surface of the channel pattern 130.

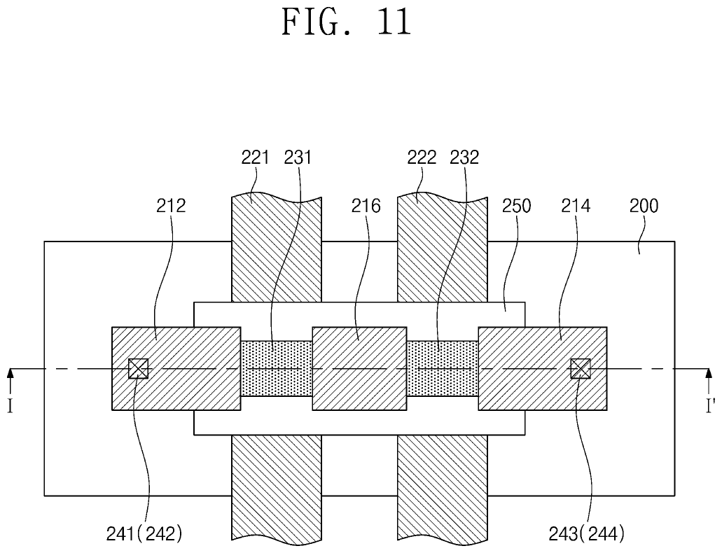

FIG. 10 is a cross-sectional view illustrating the memory device according to embodiments of the inventive concept. For simplicity of explanation, detailed descriptions on duplicated components will be omitted.

Referring to FIG. 10, the first insulation layer 150 may cover a top surface and side surfaces of the gate electrode 120. The first insulation layer 150 may directly contact the gate electrode 120.

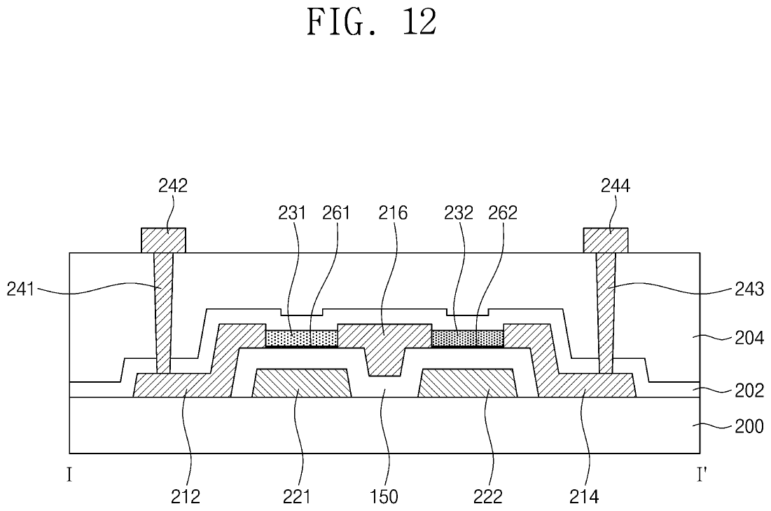

FIG. 11 is a plan view illustrating the memory device according to the embodiments of the inventive concept. FIG. 12 is a cross-sectional view taken along line I-I′ of FIG. 11.

Referring to FIGS. 11 and 12, the memory device according to the embodiments of the inventive concept may perform a calculation of NAND.

A first gate electrode 221 and a second gate electrode 222 may be provided on the top surface of a substrate 200. Each of the first gate electrode 221 and the second gate electrode 222 may include the same material as the gate electrode 120 described with reference to FIGS. 1 to 4.

A first insulation layer 150 may be disposed on the gate electrode 120. The first insulation layer 150 may cover top surfaces and side surfaces of the first gate electrode 221 and the second gate electrode 222.

The gate electrode 120 may be electrically insulated from a channel pattern 130 by the first insulation layer 150. For example, the first insulation layer 150 may include one of ZrO₂, Al₂O₃, HfO₂, SiO₂, Ta₂O₅, AlZrO, AlSiO, AlSiO and a combination thereof. The first insulation layer 150 may function as a charge inducing layer for providing a hole to an interface layer 160 that will be described later. The first insulation layer 150 may include a vacancy therein.

A first conductive pattern 212, a second conductive pattern 214, and a third conductive pattern 216 may be disposed on the first insulation layer 150. The first conductive pattern 212 and the second conductive pattern 214 may be spaced apart from each other in the first direction D1. The third conductive pattern 216 may be disposed between the first conductive pattern 212 and the second conductive pattern 214. Each of the first conductive pattern 212, the second conductive pattern 214, and the third conductive pattern 216 may include aluminum (Al), copper (Cu), silver (Ag), and gold (Au). Each of the first conductive pattern 212, the second conductive pattern 214, and the third conductive pattern 216 may include doped silicon or germanium. Each of the first conductive pattern 212, the second conductive pattern 214, and the third conductive pattern 216 may include transparent or translucent metal. For example, the translucent metal may include ITO, FTO, SnO₂ and ZnO.

A first channel pattern 231 and a second channel pattern 232 may be disposed on the first insulation layer 150. The first channel pattern 231 may be disposed between the first conductive pattern 212 and the third conductive pattern 216, and the second channel pattern 232 may be disposed between the third conductive pattern 216 and the second conductive pattern 214. The first channel pattern 231 may connect the first conductive pattern 212 and the third conductive pattern 216. The second channel pattern 232 may connect the third conductive pattern 216 and the second conductive pattern 214. For example, each of the first and second channel patterns 231 and 232 may include one of ZnO, TiO₂, In₂O₃, SnO₂ and a combination thereof. Each of the first and second channel patterns 231 and 232 may be provided through atomic layer deposition (ALD) and/or chemical vapor deposition (CVD). Each of the first and second channel patterns 231 and 232 may be in-situ provided with the first insulation layer 150. The first channel pattern 231 may have a resistance that is varied according to a voltage applied to the first gate electrode 221. The second channel pattern 232 may have a resistance that is varied according to a voltage applied to the second gate electrode 222. That is, a current value between the first conductive pattern 212 and the second conductive pattern 214 may be varied by applying a voltage to the first gate electrode 221 and the second gate electrode 222.

The memory device according to the embodiments of the inventive concept may perform a calculation of NAND. In detail, when a positive pulse applied to the first and second gate electrodes 221 and 222 is referred to as a logic signal “1”, and a state in which a voltage is not applied to or a low positive or negative voltage is applied to the first and second gate electrodes 221 and 222 is referred to as a logic signal “0”, since this is a serial connection, a current at a lower side of both devices may determine a total current. For example, when all of the first and second gate electrodes 221 and 222 are set to “1”, all of the first and second gate electrodes 221 and 222 are transited to a metal phase, and a high current is formed at both ends. Thus, an output voltage is low, and the logic signal “0” is outputted. Alternatively, when one of the first and second channels 231 and 232 is transited to a metal phase, and the other is in a semiconductor phase, a total current determined by a lower current of the semiconductor phase, and resultantly, an output voltage is outputted as the logic state “1”. Similarly, when the semiconductor phase signal is inputted to all of the first and second gate electrodes 221 and 222, the logic state is outputted as “1”. As a result, the calculation of NAND is performed.

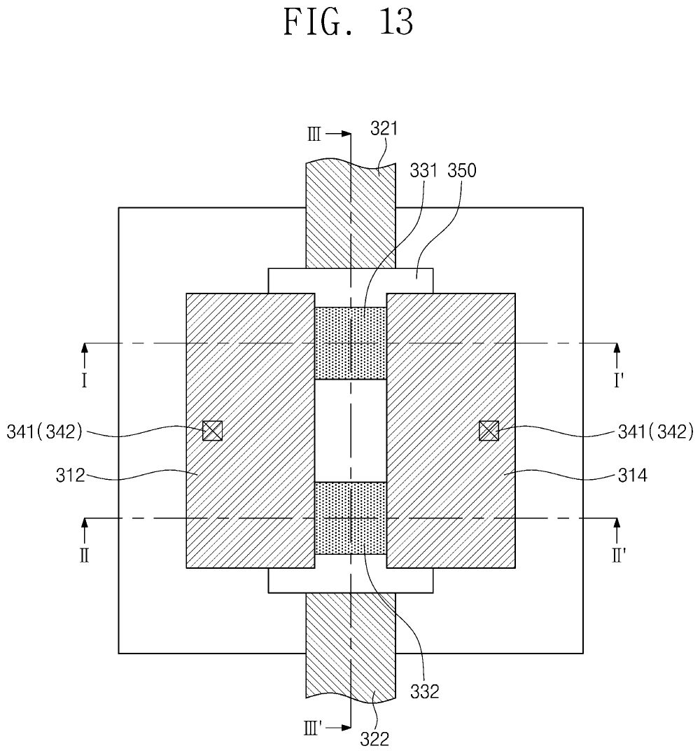

FIG. 13 is a plan view illustrating the memory device according to the embodiments of the inventive concept.

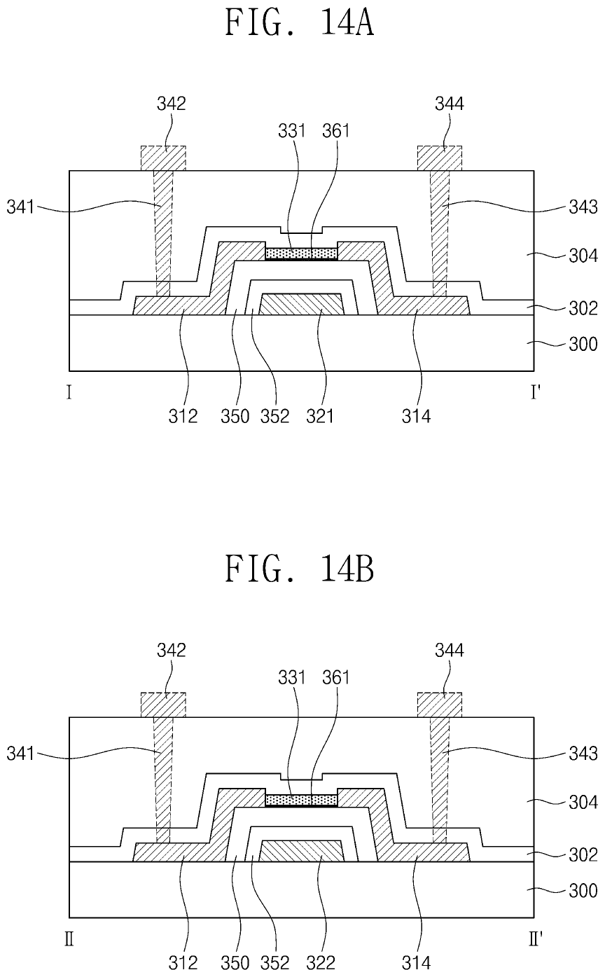

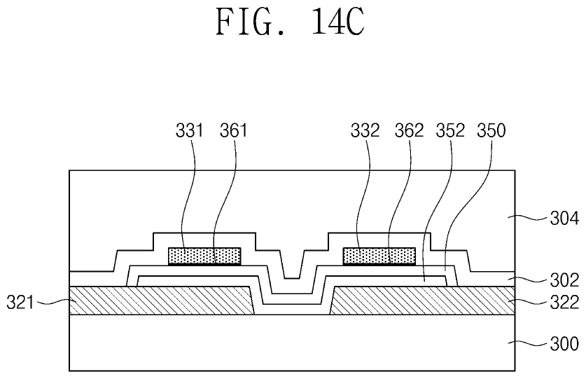

FIGS. 14A, 14B, and 14C are cross-sectional views taken along line I-I′, line II-II′, and line III-III′ of FIG. 13, respectively.

Referring to FIG. 13, the memory device according to the embodiments of the inventive concept may perform a calculation of NOR.

A first gate electrode 321 and a second gate electrode 322 may be disposed on a substrate 300. Each of the first gate electrode 321 and the second gate electrode 322 may extend in the first direction. The first gate electrode 321 and the second gate electrode 322 may be spaced apart from each other in the first direction.

A first channel pattern 331 may be disposed on the first gate electrode 321. A second channel pattern 332 may be disposed on the second gate electrode 322. For example, each of the first and second channel patterns 331 and 332 may include one of ZnO, TiO₂, In₂O₃, SnO₂ and a combination thereof. Each of the first and second channel patterns 331 and 332 may be provided through atomic layer deposition (ALD) and/or chemical vapor deposition (CVD).

A first insulation layer 350 may be disposed between the first channel pattern 331 and the first gate electrode 321 and between the second channel pattern 332 and the second gate electrode 322. For example, the first insulation layer 350 may include one of ZrO₂, Al₂O₃, HfO₂, SiO₂, Ta₂O₅, AlZrO, AlSiO, AlSiO and a combination thereof. The first insulation layer 350 may function as a charge inducing layer for providing a hole to an interface layer 321. The first insulation layer 350 may include a vacancy therein.

A second insulation layer 352 may be disposed between the first insulation layer 350 and the first and second gate electrodes 321 and 322. The second insulation layer 352 may have an oxygen atom content ratio (atomic %) less than that of the first insulation layer 350.

A first conductive pattern 312 and a second conductive pattern 314 may be disposed on the first insulation layer 350. The first conductive pattern 312 and the second conductive pattern 314 may be spaced apart from each other. Each of the first conductive pattern 312 and the second conductive pattern 314 may include aluminum (Al), copper (Cu), silver (Ag), and gold (Au). Each of the first conductive pattern 312 and the second conductive pattern 314 may include doped silicon or germanium. Each of the first conductive pattern 312 and the second conductive pattern 314 may include transparent or translucent metal. For example, the translucent metal may include ITO, FTO, SnO₂ and ZnO.

The first channel pattern 331 may connect the first conductive pattern 312 and the second conductive pattern 314 in the second direction. The second channel pattern 332 may connect the first conductive pattern 312 and the second conductive pattern 314 in the second direction.

The memory device according to the embodiments of the inventive concept may perform a calculation of NOR. A positive pulse applied to the first and second gate electrodes 321 and 322 may be defined as a logic signal “1”, and a state in which a voltage is not applied to or a low positive or negative voltage is applied to the first and second gate electrodes 321 and 322 may be defined as a logic signal “0”. An amount of a current flowing through the first channel pattern 331 and the second channel pattern 332 may be varied by a logic signal applied to the first gate electrode 321 and the second gate electrode 322.

Since the first channel pattern 331 and the second channel pattern 332 are connected in parallel, a current at a side through which a more current flows may determine a total current between the first conductive pattern 312 and the second conductive pattern 314. For example, when the logic signal “1” is applied to all of the first channel pattern 331 and the second channel pattern 332, the first channel pattern 331 and the second channel pattern 332 may be transited to a metal phase, and a high current may be provided at both ends of the first conductive pattern 312 and the second conductive pattern 314. Thus, an output voltage may be low, and the logic state “0” may be outputted. When one of the first channel pattern 331 and the second channel pattern 332 is transited to a metal phase, and the other is in a semiconductor phase, the total current may be determined by a higher current of the metal phase. Here, the output voltage may be outputted as the logic state “0”. When all of the first channel pattern 331 and the second channel pattern 332 are transited to the semiconductor phase, the logic state “1” may be outputted.

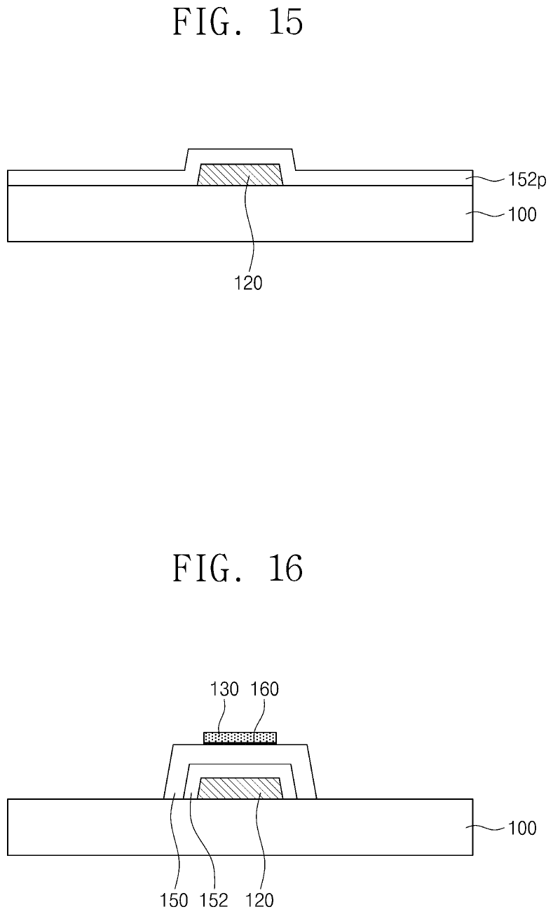

FIGS. 15 to 18 are cross-sectional views illustrating a method for manufacturing the memory device according to the embodiment of the inventive concept.

Referring to FIG. 15, a gate electrode 120 on a substrate and an insulation layer 152p on the gate electrode 120 may be formed. The forming of the gate electrode 120 may include forming a conductive layer (not shown) on the substrate and patterning the conductive layer. The insulation layer 152p may be conformally formed on the substrate 100 and the gate electrode 120.

Referring to FIG. 16, a second insulation layer 152 may be formed by patterning the insulation layer 152p. Thereafter, a first insulation layer 150, an interface layer 160, and a channel pattern 130 may be sequentially formed on the second insulation layer 152.

The forming of the first insulation layer 150 may include forming an insulation layer (not shown) covering the substrate 100 and the second insulation layer 152 and patterning the insulation layer. Thereafter, a process of varying an oxygen atom content ratio (atomic %) of the first insulation layer 150 may be performed. According to the embodiments, the oxygen atom content ratio (atomic %) of the first insulation layer 150 may be reduced to be lower than that of the second insulation layer 152 by desorbing hydrogen atoms existing in the first insulation layer 150. The desorbing of the oxygen atoms may include, e.g., performing a high pressure hydrogen heat treatment process to the first insulation layer 150. The first insulation layer 150 from which oxygen atoms are desorbed may have a density of oxygen vacancy greater than that of the second insulation layer 152. The interface layer 160 may be formed through, e.g., the high pressure hydrogen heat treatment process to the first insulation layer 150. The interface layer 160 may have a hydrogen atom content ratio (atomic %) greater than that of the first insulation layer 150.

The interface layer 160 and the channel pattern 130 may be disposed on the first insulation layer 150. The forming of the channel pattern 130 may include depositing an oxide semiconductor layer (not shown) on the interface layer 160 and patterning the oxide semiconductor layer.

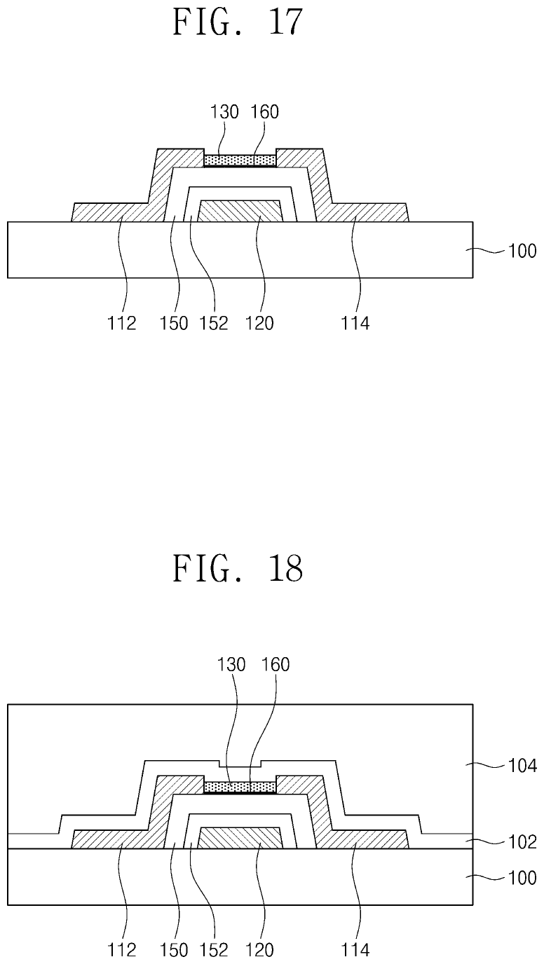

Referring to FIG. 17, a first conductive pattern 112 and a second conductive pattern 114 may be formed. The forming of the first conductive pattern 112 and the second conductive pattern 114 may include forming a metal layer and patterning the metal layer.

Referring to FIG. 18, a first interlayer insulation layer 102 and a second interlayer insulation layer 104 may be formed. The first interlayer insulation layer 102 may be conformally formed on the first and second conductive patterns 112 and 114 and the channel pattern 130. The second interlayer insulation layer 104 may be formed on the first interlayer insulation layer 102 to have a flat top surface. Thereafter, first and second contact plugs 141 and 143 and first and second conductive pads 142 and 144 may be formed as illustrated in FIG. 3.

According to the embodiments, the memory device may stably operate and have a low power consumption without accompanying phase transitions.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed. Therefore, the embodiments described above include exemplary in all respects and not restrictive, but it should be understood.

What is claimed is:

1. A memory device comprising:
a gate electrode;
a first insulation layer on the gate electrode;
a first conductive pattern and a second conductive pattern, which are spaced apart from each other on the first insulation layer;
a channel pattern disposed on the first insulation layer to connect the first conductive pattern and the second conductive pattern; and
an interface layer disposed between the channel pattern and the first insulation layer and having a hydrogen atom content ratio (atomic %) greater than that of the first insulation layer.

2. The memory device of claim 1, wherein the first insulation layer and the channel pattern are spaced apart from each other with the interface layer therebetween.

3. The memory device of claim 1, wherein the interface layer has a thickness less than that of each of the first insulation layer and the channel pattern.

4. The memory device of claim 1, further comprising a second insulation layer disposed between the first insulation layer and the gate electrode,
wherein the first insulation layer and the second insulation layer have different oxygen atom content ratios (atomic %).

5. The memory device of claim 1, wherein the interface layer covers at least a portion of a side surface of the first insulation layer.

6. The memory device of claim 1, further comprising a pulse generator that is electrically connected to the gate electrode.

7. A memory device comprising:
a first gate electrode and a second gate electrode, which are spaced apart from each other in a first direction;
a first channel pattern on the first gate electrode;
a second channel pattern on the second gate electrode;
a first insulation layer disposed between the first gate electrode and the first channel pattern and between the second gate electrode and the second channel pattern; and
a first conductive pattern and a second conductive pattern on the first insulating layer, wherein the first conductive pattern and the second conductive pattern are spaced apart from each other in a second direction crossing the first direction,
wherein each of the first channel pattern and the second channel pattern connects the first conductive pattern and the second conductive pattern.

8. The memory device of claim 7, further comprising a first interface layer disposed between the first channel pattern and the first insulation layer and a second interface layer disposed between the second channel pattern and the first insulation layer.

9. The memory device of claim 7, wherein each of the first interface layer and the second interface layer has a hydrogen atom content ratio (atomic %) greater than that of the first insulation layer.

10. The memory device of claim 7, further comprising a second insulation layer disposed between the first insulation layer and the first and second gate electrodes,
wherein the first insulation layer and the second insulation layer have different oxygen atom ratios (atomic %).
